(19) United States
(12) Patent Application Publication
(10) Pub. No.: US 2026/0360442 A1
(43) Pub. Date: Nov. 12, 2026

(54) READ TIMING SAVINGS BY TEMPORARILY APPLYING BIT LINE KICK DURING SAVE CURRENT CONSUMPTION MODE

(71) Applicant: Sandisk Technologies, Inc., Milpitas, CA (US)

(72) Inventors: Shubham Awate, San Jose, CA (US); Jiacen Guo, Cupertino, CA (US); Xiang Yang, Santa Clara, CA (US)

(21) Appl. No.: 19/200,180

(22) Filed: May 6, 2025

(51) Int. Cl. G11C 16/26; G11C 16/04; G11C 16/24

(52) U.S. Cl. CPC G11C 16/26; G11C 16/0483; G11C 16/24

(57) ABSTRACT

A memory apparatus includes memory cells each connected to one of a plurality of word lines. The memory cells are disposed in memory holes connected to bit lines and are configured to retain a threshold voltage corresponding to data states. A control means is configured to perform reads on a selected one of the plurality of word lines for each of a plurality of groupings of ones of the data states in a read operation. The control means is also configured to ramp a bit line voltage applied to ones of the bit lines connected the memory holes of the memory cells being read in the read operation to a bit line kick voltage for a predetermined kick time following a word line settling time in which the selected ones of the plurality of word lines ramp down to read voltages each associated with one of the data states.

### FIELD

This application relates to non-volatile memory apparatuses and the operation of non-volatile memory apparatuses.

### BACKGROUND

This section provides background information related to the technology associated with the present disclosure and, as such, is not necessarily prior art.

In order to improve read and program performance of memory devices, multiple charge storage elements or memory transistors in an array are read or programmed in parallel. Thus, a “page” of memory elements are typically read or programmed together. Both reading and verifying operations are performed by executing one or more sensing cycles in which the conduction current or threshold voltage of each memory cell of the page is determined relative to a demarcation value. In general, if the memory is partitioned into n states, there will be at least n−1 sensing passes or levels to resolve all possible memory states. In many implementations, each sensing cycle may also involve two or more passes or levels.

Power consumption is one important consideration of memory devices. With massively parallel sensing, the number of memory cells with conduction current flow will compound. Therefore, there is a need for high performance and high capacity non-volatile memory apparatuses with reduced power consumption during sensing operations.

### SUMMARY

This section provides a general summary of the present disclosure and is not a comprehensive disclosure of its full scope or all of its features and advantages.

An object of the present disclosure is to provide a memory apparatus and a method of operating the memory apparatus that address and overcome the above-noted shortcomings.

Accordingly, it is an aspect of the present disclosure to provide a memory apparatus including memory cells each connected to one of a plurality of word lines. The memory cells are disposed in memory holes each connected to one of a plurality of bit lines. The memory cells are configured to retain a threshold voltage corresponding to one of a plurality of data states. The memory apparatus also includes a control means configured to perform a plurality of reads on a selected one of the plurality of word lines for each of a plurality of groupings of ones of the plurality of data states in a read operation. The control means is also configured to ramp a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

According to another aspect of the disclosure, a controller in communication with a memory apparatus including memory cells each connected to one of a plurality of word lines is also provided. The memory cells are disposed in memory holes each connected to one of a plurality of bit lines. The memory cells are configured to retain a threshold voltage corresponding to one of a plurality of data states. The controller is configured to instruct the memory apparatus to perform a plurality of reads on a selected one of the plurality of word lines for each of a plurality of groupings of ones of the plurality of data states in a read operation. The controller is also configured to instruct the memory apparatus to ramp a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

According to an additional aspect of the disclosure a method of operating a memory apparatus is provided. The memory apparatus includes memory cells each connected to one of a plurality of word lines. The memory cells are disposed in memory holes each connected to one of a plurality of bit lines. The memory cells are configured to retain a threshold voltage corresponding to one of a plurality of data states. The method includes the step of performing a plurality of reads on a selected one of the plurality of word lines for each of a plurality of groupings of ones of the plurality of data states in a read operation. The method also includes the step of ramping a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic diagram illustrating one embodiment of a memory device according to aspects of the disclosure;

FIG. 2 is a schematic diagram illustrating one embodiment of a flash non-volatile memory cell according to aspects of the disclosure;

FIG. 3 is a schematic diagram illustrating one embodiment of the relation between a source-drain current and a control gate voltage for eight different charge levels that the floating gate of a memory cell may be selectively storing at any one time according to aspects of the disclosure;

FIG. 4 is a schematic diagram illustrating one embodiment of threshold voltage distributions of a memory array with memory cells operable in eight memory states according to aspects of the disclosure;

FIG. 5 is a schematic diagram illustrating one embodiment of a sense block for sensing a conduction current of a memory cell for read operations or verify operations according to aspects of the disclosure;

FIG. 6 is a flowchart illustrating one embodiment of a method of sensing the memory states of a memory device according to aspects of the disclosure;

FIG. 7A is a schematic read level chart illustrating one embodiment of a read operation utilizing the method of FIG. 6 according to aspects of the disclosure;

FIG. 7B is a chart illustrating one embodiment of locking out or inhibiting conducting cells during a read level during a read operation following a read scheme of read level chart of FIG. 7A according to aspects of the disclosure;

FIG. 8 is a schematic diagram illustrating another embodiment of 3-bit gray coding represented by eight memory states according to aspects of the disclosure;

FIG. 9A is a schematic read level chart illustrating one embodiment of a read operation discerning the Gray code of FIG. 8 according to aspects of the disclosure;

FIG. 9B is a chart illustrating one embodiment of locking out or inhibiting conducting cells during a read level during a read operation following a read scheme of read level chart of FIG. 9A according to aspects of the disclosure;

FIG. 10 is a timing diagram that illustrates the operation of the sense module shown in FIG. 5 during the 3-pass read as applied to a NAND memory cell that is part of a memory page in parallel according to aspects of the disclosure;

FIG. 11 shows an example series of read voltages applied to a selected word line for both a normal read and a reverse read when reading a middle page according to aspects of the disclosure;

FIG. 12 is a table illustrating sequences or series of the data states being sensed for each of a lower page, middle page, and upper page for both the normal read and the reverse read according to aspects of the disclosure;

FIG. 13 shows a plot of resistive-capacitive delay versus generations of memory apparatuses according to aspects of the disclosure;

FIG. 14 is a plot of the bit line voltage applied to the bit lines, word line voltage applied to a selected one of the word lines, and the cell source voltage to the source line during a portion of a read operation according to aspects of the disclosure;

FIG. 15 is a plot of failure bit count versus the read time for two periods of time during a read operation with the current consumption savings with and without temporarily cutting off the bit line shown in FIG. 14 according to aspects of the disclosure;

FIG. 16 shows diagrams showing the quantity of the two periods of time utilized in read operations involving lower pages, middle pages, and upper pages when the memory cells read are triple level and involving lower pages, middle pages, upper pages, and top pages when the memory cells read are four level cells along with average read time and change in read time due to the current consumption savings with temporarily cutting off the bit line shown in FIG. 14 according to aspects of the disclosure;

FIG. 17 is a plot of the bit line voltage applied to the bit lines, word line voltage applied to a selected one of the word lines, and the cell source voltage to the source line during a portion of a read operation in which the read timing margin is increased by decreasing the bit line settling time without significantly changing the current consumption savings realized by the scheme shown in FIG. 14 according to aspects of the disclosure;

FIG. 18 is a plot of failure bit count versus the read time for two periods of time during a read operation with the current consumption savings using the current consumption save mode by temporarily cutting off the bit line, as shown in FIG. 14 during the word line settling time with and without the bit line kick voltage of FIG. 17 according to aspects of the disclosure; and

FIGS. 19 and 20 illustrate steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of operation of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

In some memory devices or apparatuses, memory cells are joined to one another such as in NAND strings in a block or sub-block. Each NAND string comprises a number of memory cells connected in series between one or more drain-side SG transistors (SGD transistors), on a drain-side of the NAND string which is connected to a bit line, and one or more source-side SG transistors (SGS transistors), on a source-side of the NAND string which is connected to a source line. Further, the memory cells can be arranged with a common control gate line (e.g., word line) which acts a control gate. A set of word lines extends from the source side of a block to the drain side of a block. Memory cells can be connected in other types of strings and in other ways as well.

In a 3D memory structure, the memory cells may be arranged in vertical strings in a stack, where the stack comprises alternating conductive and dielectric layers. The conductive layers act as word lines which are connected to the memory cells. The memory cells can include data memory cells, which are eligible to store user data, and dummy or non-data memory cells which are ineligible to store user data.

Before programming certain non-volatile memory devices, the memory cells are typically erased. For some devices, the erase operation removes electrons from the floating gate of the memory cell being erased. Alternatively, the erase operation removes electrons from the charge trapping layer.

During a program operation, the memory cells are programmed according to a word line programming order. For example, the programming may start at the word line at the source side of the block and proceed to the word line at the drain side of the block. In one approach, each word line is completely programmed before programming a next word line. For example, a first word line, WL0, is programmed using one or more programming pulses until the programming is completed. Next, a second word line, WL1, is programmed using one or more programming pulses until the programming is completed, and so forth. A programming pulse may include a set of increasing program voltages which are applied to the word line in respective program loops or program-verify iterations. Verify operations or stages may be performed after each program voltage to determine whether the memory cells have completed programming. When programming is completed for a memory cell, it can be inhibited from further programming while programming continues for other memory cells in subsequent program loops.

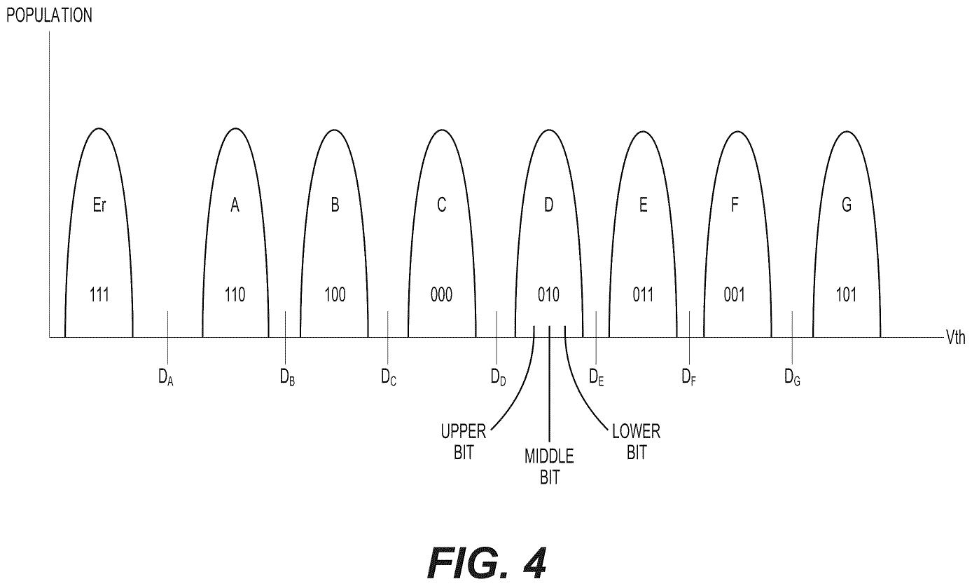

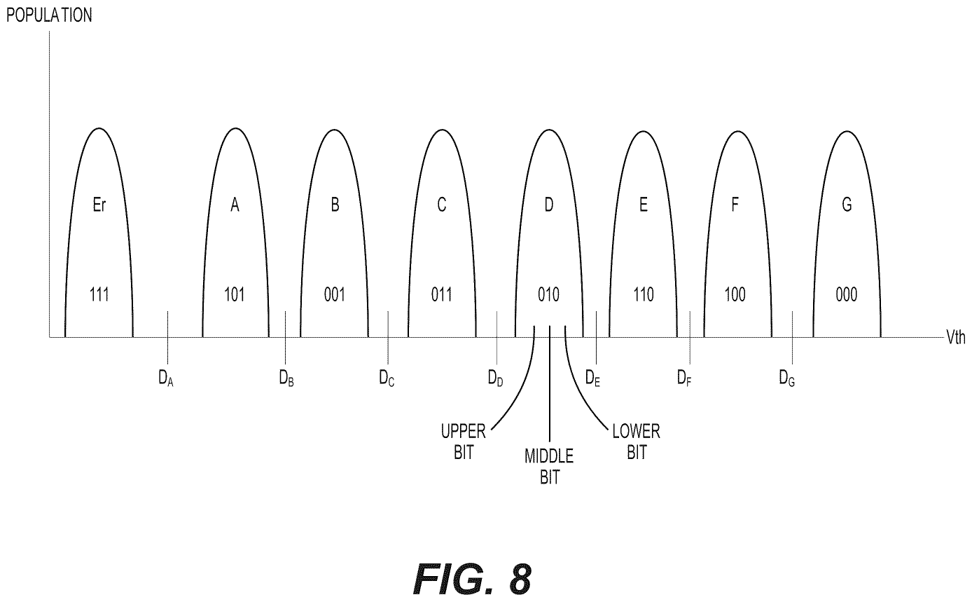

Each memory cell may be associated with a data state according to write data in a program command. Based on its data state, a memory cell will either remain in the erased state or be programmed to a programmed data state. For example, in a three bit per cell memory device, there are eight data states including the erased state and the programmed state (see e.g., FIGS. 4 and 8).

After the memory cells are programmed, the data can be read back in a read operation. A read operation can involve applying a series of read voltages to a word line while sensing circuitry determines whether cells connected to the word line are in a conductive or non-conductive state. If a cell is in a non-conductive state, the threshold voltage Vt or Vth of the memory cell exceeds the read voltage. The read voltages are set at levels which are expected to be between the threshold voltage levels of adjacent data states. The timing of voltages applied to selected ones of the word lines relative to those applied to bit lines coupled to the memory cells being read can affect both current consumption of the memory apparatus as well as read timing margin.

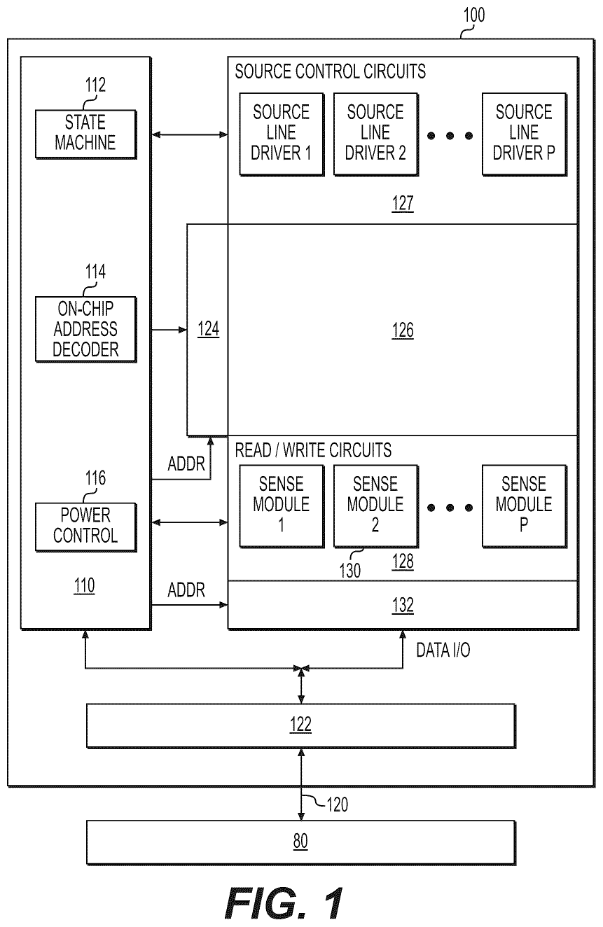

FIG. 1 is a schematic diagram illustrating one embodiment of a memory device 100. Memory device 100 includes a memory array 126 of memory cells, such as a two-dimensional array of memory cells or a three-dimensional array of memory cells. The memory array 126 may include memory cells according to an NAND flash type or NOR flash type architecture. Memory cells in a NAND configuration are accessed as a group and are typically connected in series. A NAND memory array is composed of multiple strings in which each string is composed of multiple memory cells sharing a bit line and accessed as a group. Memory cells in a NOR configuration may be accessed individually. NAND flash and NOR flash memory cells may be configured for long-term storage of information as non-volatile memory retaining information after power on/off cycles. Memory array 126 may also be other types of memory cells programmable to store multiple bits of data per cell as non-volatile memory or volatile memory and may be other types of memory cells in other configurations besides NAND or NOR configurations. Memory device 100 may include multiple dies of memory arrays 126.

Memory array 126 is addressable by word lines via a row decoder 124 and by bit lines via a column decoder 132. Row decoder 124 selects one or more word lines and the column decoder 132 selects one or more bit lines in order to apply appropriate voltages to the respective gates/drains of the addressed memory transistor.

Read/write circuits 128 are provided to read or write (program) the memory states of addressed memory transistors. Read/write circuits 128 include multiple sense modules 130 (sensing circuitry) that allow a page (or other unit) of memory cells to be read or sensed in parallel. Each sense module 130 includes bit line drivers and circuits for sensing.

Control circuitry 110 cooperates with read/write circuits 128 to perform memory operations on memory array 126. Control circuity 110 may include a state machine 112, an on-chip address decoder 114, and a power control module 116. State machine 112 provides chip-level control of memory operations. On-chip address decoder 114 provides an address interface between a host or a memory controller to the hardware address used by decoders 124 and 132. Power control module 116 controls the power and voltages supplied to the word lines and bit lines during memory operations. Control circuitry 110 may include drivers for word lines, source side select lines (SGS), drain side select lines (SGD), and source lines. Control circuitry 110 is also in communication with source control circuits 127, which includes source line driver circuits used to drive varies voltages on the individual source lines.

Memory device 100 includes a controller 122 which operates with a host 80 through a link 120. Commands and data are transferred between a host and controller 122 via a link 120. Link 120 may be via a connection (e.g., a communication path), such as a bus or a wireless connection.

Memory device 100 may be used as storage memory, a main memory, a cache memory, a backup memory, or a redundant memory. Memory device 100 may be an internal storage drive, such as a notebook hard drive or a desktop hard drive. Memory device 100 may be a removable mass storage device, such as, but not limited to, a handheld, removable memory device, such as a memory card (e.g., a secure digital (SD) card, a micro secure digital (micro-SD) card, or a multimedia card (MMC)) or a universal serial bus (USB) device. Memory device 100 may take the form of an embedded mass storage device, such as an eSD/eMMC embedded flash drive, embedded in host 80. Memory device 100 may also be any other type of internal storage device, removable storage device, embedded storage device, external storage device, or network storage device.

Memory device 100 may be directly coupled to host 80 or may be indirectly coupled to host 80 via a network. For example, the network may include a data center storage system network, an enterprise storage system network, a storage area network, a cloud storage network, a local area network (LAN), a wide area network (WAN), the Internet, and/or another network.

Instructions may be executed by various components of memory device 100, such as by controller 100, controller circuitry 110, row decoder 124, column decoder 132, read/write circuits 128, source control circuits 127, logic gates, switches, latches, application specific integrated circuits (ASICs), programmable logic controllers, embedded microcontrollers, and other components of memory device 100.

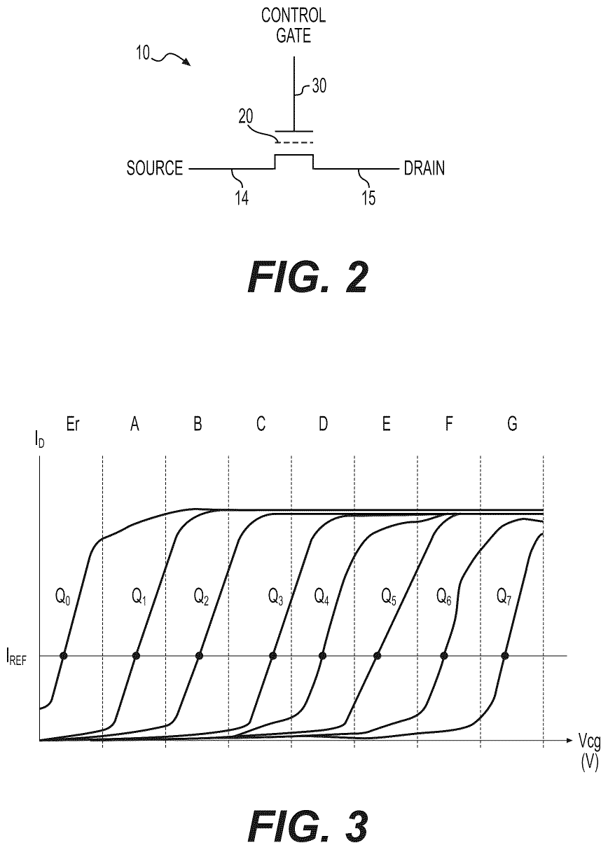

FIG. 2 is a schematic diagram illustrating one embodiment of a flash non-volatile memory cell 10. Memory cell 10 can be implemented by a field-effect transistor having a charge storage unit 20, such as a floating gate or a dielectric layer. Memory cell 10 also includes a source 14, a drain 16, and a control gate 30. A memory state of memory cell 10 may be read by sensing the conduction current across the source and drain electrodes of the cell when a reference voltage is applied to the control gate 30. For each given charge on the floating gate of a cell, a corresponding conduction current with respect to a fixed reference control gate voltage may be detected. A range of charge programmable onto the floating gate defines a corresponding threshold voltage window or a corresponding conduction current window of the memory states of memory cell 10.

FIG. 3 is a schematic diagram illustrating one embodiment of the relation between a source-drain current I_{D} and a control gate voltage V_{CG} for eight different charge levels Q0-Q7 that the floating gate of a memory cell, such as memory cell 10 of FIG. 2, may be selectively storing at any one time. The eight curves represent eight charge levels on a floating gate of a memory cell corresponding to eight possible memory states. Eight possible memory states representing one erased memory state ER and seven programmed states A, B, C, D, E, F, and G may be demarcated by partitioning the threshold window into eight regions. For example, if a reference current I_{REF} is used, then a cell programmed with a charge level Q1 may be considered to be in an A memory state since its curve intersects with I_{REF} in the region of the A threshold voltage window. If a reference current I_{REF} is used, then a cell programmed with a charge level Q3 may be considered to be in a C memory state since its curve intersects with I_{REF} in the region of the C threshold voltage window.

FIG. 4 is a schematic diagram illustrating one embodiment of threshold voltage distributions of a memory array with memory cells operable in eight memory states. The possible threshold voltages of each memory cell spans a threshold window which is partitioned into eight regions to demarcate eight possible memory states, “Er”, “A”, “B”, “C”, “D”, “E”, “F” and “G”. “Er” is an erased state or a ground state and “A” through “G” are seven progressively programmed states. During a read operation, the eight states may be demarcated by seven demarcation breakpoints of demarcation threshold voltages, D_{A}, D_{B}, D_{C}, D_{D}, D_{E}, D_{F}, and D_{G}.

FIG. 4 also shows one embodiment of 3-bit gray coding represented by the eight possible memory states. Each of the eight memory states represented a triplet of upper, middle, and lower bits. In this embodiment, erased memory state represents “111”, A memory state represents “110”, B memory state represents “100”, C memory state represents “000”, D memory state represents “010”, E memory state represents “011”, F memory state represents “001”, and G memory state represents “101.” The 3 code bits, “lower”, “middle” and “upper” bits, may be read or programmed separately. For example, in a first round, the lower bits of the memory cells may be read. In a second round, the middle bits of the memory cells may be read. In a third round, the upper bits of the memory cells may be read. Similarly in programming, in a first round the lower bits of the memory cells may be programmed and verified. In a second round the middle bits of the memory cells may be programmed and verified. In a third round the upper bits of the memory cells may be programmed and verified.

FIGS. 3 and 4 show a memory cell having eight memory states and operating as a triple-level cell (TLC) or X3 cell storing 3 bits/cell. In other embodiments, a memory cell may have more than eight memory states. For example, a memory cell may have sixteen memory states operating as a quadruple-level memory cell (QLC) or X4 cell storing 4 bits/cell.

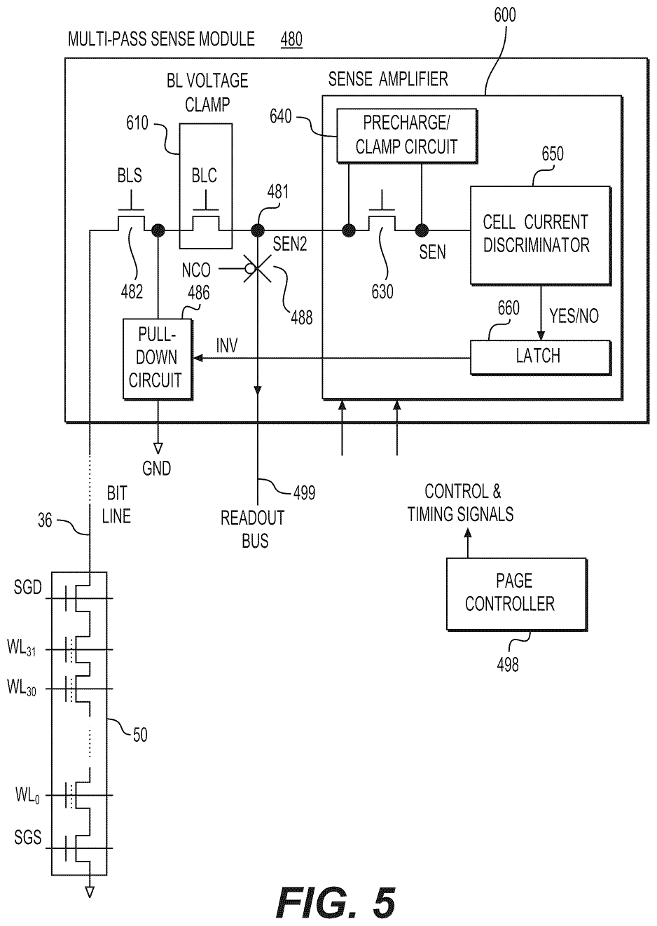

FIG. 5 illustrates schematically in more details a preferred sense module shown as sense module 130 in FIG. 1. The sense module 480 senses the conduction current of a memory cell in a NAND chain 50 via a coupled bit line 36. It has a sense node 481 that can be selectively coupled to a bit line, a sense amplifier 600 or a readout bus 499. Initially, an isolation transistor 482, when enabled by a signal BLS connects the bit line 36 via a bit line voltage clamp 610 (controlled by a signal BLC) to the sense node 481. The sense amplifier 600 senses a signal SEN2 at the sense node 481. The sense amplifier includes a precharge/clamp circuit 640, a cell current discriminator 650 and a latch 660. In this example, the NAND chain 50 has thirty-two memory cells in series with their control gates connected to word lines WL₀-WL₃₁ respectively. The NAND chain 50 is coupled to ground via a select transistor controlled by a signal SGS and coupled to the bit line 36 via a select transistor controlled by a signal SGD.

The sense module 480 enables the conduction current of the selected memory cell in the NAND chain to be sensed. Prior to sensing, the voltages to the gates of the selected memory cell must be set via the appropriate word lines and bit line. As will be described in more detail later, the precharge operation starts with the unselected word line charging to a voltage Vread followed by charging the selected world line to a predetermined threshold voltage Vt(i) for a given memory state under consideration. Then the precharged circuit 640 brings the bit line voltage to a predetermined drain voltage appropriate for sensing. This will induce a source-drain conduction current to flow in the selected memory cell in the NAND chain 50, which is detected from the channel of the NAND chain via a coupled bit line 36. The conduction current is a function of the charge programmed into the memory cell and the applied Vt(i) when there exists a nominal voltage difference between the source and drain of the memory cell.

When the Vt(i) voltage is stable, the conduction current or the programmed threshold voltage of the selected memory cell can be sensed via the coupled bit line 36. The sense amplifier 600 is then coupled to the sense node to sense the conduction current in the memory cell. The cell current discriminator 650 serves as a discriminator or comparator of current levels. It effectively determines whether the conduction current is higher or lower than a given demarcation current value I₀(j). If it is higher, the latch 660 is set to a predetermined state with the signal INV=1.

A pull-down circuit 486 is activated in response to the latch 660 setting the signal INV to HIGH. This will pull down the sense node 481 and therefore the connected bit line 36 to ground voltage. This will inhibit the conduction current flow in the memory cell 10 (i.e., lock out) irrespective of the control gate voltage since there will be no voltage difference between its source and drain.

According to an aspect, there can be a page of memory cells being operated on by a corresponding number of multi-pass sense modules 480. A page controller 498 supplies control and timing signals to each of the sense modules. The page controller 498 cycles each of the multi-pass sense module 480 through a predetermined number of passes (j=1 to N) and also supplies a predetermined demarcation current value I₀(j) for each pass. As is well known in the arts, the demarcation current value can also be implemented as a demarcation threshold voltage, or time period for sensing. After the last pass, the page controller 498 enables a transfer gate 488 with a signal NCO to read the state of the sense node 481 as sensed data to a readout bus 499. In all, a page of sense data will be read out from all the multi-pass modules 480. Similar sense modules have been disclosed in U.S. Pat. No. 7,046,568 granted May 16, 2006 to Cernea et al., entitled “MEMORY SENSING CIRCUIT AND METHOD FOR LOW VOLTAGE OPERATION”. The entire disclosure of U.S. Pat. No. 7,046,568 is herein incorporated by reference.

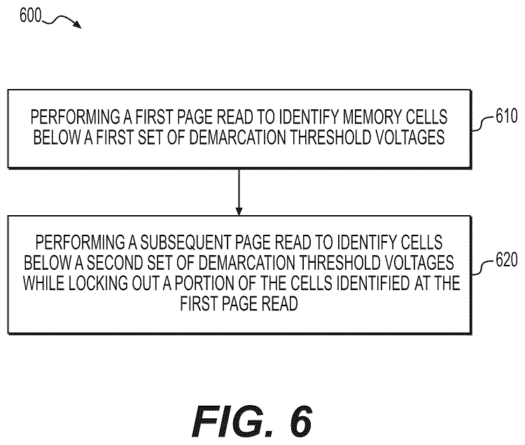

FIG. 6 is a flowchart illustrating one embodiment of a method 600 of sensing a memory state of the memory cells of a memory device, such as memory device 100 of FIG. 1 and sense module 130, 480 of FIG. 1 and FIG. 5, but other memory devices and sense modules are possible.

In process 610, a first page read may be performed. The first page read includes one or more read levels of a first series of one or more demarcation threshold voltages. The first page read identifies memory cells with threshold voltages below the first series of one or more demarcation threshold voltages.

In process 620, a subsequent page read may be performed. The subsequent page read includes one or more read levels of a second series of one or more demarcation threshold voltages. The subsequent page read identifies memory cells with threshold voltages below the second series of one or more demarcation threshold voltages. During the subsequent page read, a portion of the memory cells identified at process 610 are locked out during one or more of the read levels in the subsequent page read. During the subsequent page read, a portion of the memory cells identified in a prior read level in the current page read may also be locked out during subsequent read levels in the current page read.

Peak channel current (Icc) is an important metric for the memory device or apparatus and is defined as the highest Icc level during the given operation. Thus, peak Icc is significant to the power management of the memory device or apparatus. Method 600 may be used to reduce I_{CC} or current consumed by memory array 126 or memory die during read operations. In read operations of more than one page read, memory cells identified in a first page read may be locked out in a subsequent page read to conserve current consumed. Prior page read information alone or in combination with prior read level information in a current page read may be used to lockout additional number of memory cells during a current page read to reduce Icc during a read operation.

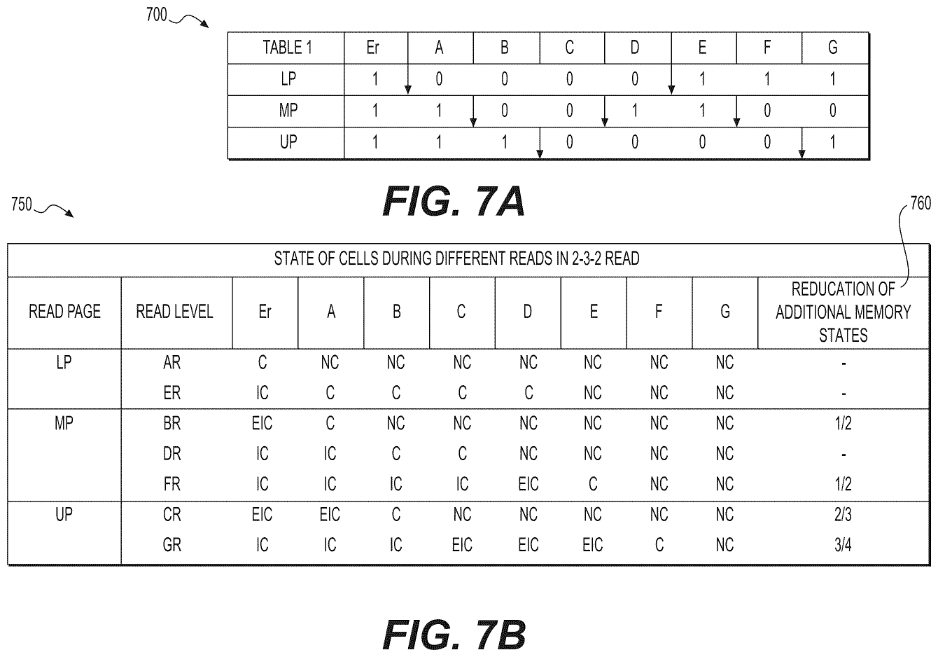

FIG. 7A is a read level chart 700 illustrating one embodiment of a read operation utilizing the method 600 of FIG. 6. Read level chart 700 illustrates a read operation discerning the lower bits, middle bits, and upper bits of the 8-state memory encoded with a Gray code of FIG. 4 using a 2-3-2 read scheme. The read scheme includes three pages of reads of a lower page read, a middle page read, and an upper page read. In the lower page read, two demarcation threshold voltages are provided to identify memory cells with two read levels to discern the lower bits. In the middle page read, three demarcation threshold voltages are provides to identify memory cells with three read levels to discern the middle bits. In the upper page read, two demarcation threshold voltages are provides to identify memory cells with two read levels to discern the upper bits. In the read scheme, certain memory cells in certain memory states are locked out during a read level so that power is not drained unnecessarily. Memory cells may be locked out by inhibiting the conductive cells or by having their conduction currents turned off by grounding their bit lines (or connect to SGS transistor source node value if NAND string source is set to non-zero).

FIG. 7B is a table 750 illustrating one embodiment of locking out or inhibiting conducting cells during a read level to reduce I_{CC} during a read operation following a read scheme of read level chart 700 of FIG. 7A. The entry “c” represents non-inhibited conductive cells during a particular read level. The entry “nc” represents non-conductive cells during a particular read level. The entry “ic” represents inhibited conductive cells during a particular read level. These cells are identified based on a prior read level from the same page this is being read. The entry “eic” represents extra or additional inhibited conductive cells during a particular read level in which the extra or additional inhibited conductive cells are identified from a prior read level from a prior page read.

A lower page read comprising a two level read with a first level A read relative to demarcation of D_{A} and a second level E read relative to demarcation threshold voltage D_{E}, may discern the lower bits of the memory cells. In the first level A read, those memory cells with programmed threshold voltages less than the demarcation threshold voltage D_{A} are detected. In the second level E read, those memory cells with programmed threshold voltages less than the demarcation threshold voltage D_{E} are detected. In the second level E read, Erased state memory cells previously identified under A read from the current lower page read may be locked out during E read.

A middle page read comprising a three level read with a first level B read relative to demarcation threshold voltage of D_{B}, a second level D read relative to demarcation threshold voltage D_{D}, and a third level F read relative to demarcation threshold D_{F} may discern the middle bits of the memory cells. In the first level B read, those memory cells with programmed threshold voltages less than the demarcation threshold voltage D_{B} are detected. In the first level B read, Erased state memory cells previously identified under A read in the prior lower page read are locked out. In the second level D read, those memory cells with programmed threshold voltages less than the demarcation threshold voltage D_{D} are detected. In the second level D read, Erased and A state memory cells previously identified under B read in the current middle page may be locked our during D read. In the third level F read, those memory cells with programmed threshold voltages less than the demarcation threshold voltage D_{F} are detected. In the third level F read, Erased, A, B, C, and D state memory cells previously identified under E read from the prior lower page read may be locked out during F read.

An upper page read comprising a two level read with a first level C read relative to demarcation of D_{C} and a second level G read relative to demarcation threshold voltage D_{G} may discern the upper bits. In the first level C read, those memory cells with programmed threshold voltages less than the demarcation threshold voltage D, are detected. In the first level C read, Erased and A state memory cells previously identified under B read from the prior middle page read may be locked out during C read. In the second level G read, those memory cells with programmed threshold voltages less than the demarcation threshold voltage D_{G} are detected. In the second level G read, Erased, A, B, C, D, and E previously detected under F read from prior middle page read may be locked out.

Locking out additional memory cells identified in a prior read level from a prior page read as compared to only locking out memory cells identified in a prior level from a current page read reduces the number of cells sensed and reduces the Icc or power consumed. Column 760 of table 750 indicates the fraction or percentage of additional memory states locked out using prior read level from a prior page read relative to the remaining conductive memory states identified simply by using a prior read level from a current page read. The additional memory states locked out are identified from a prior read level for a prior page read which could not have been identified from a prior level in a current page read.

For example, in B read in a middle page read, additional Erased state conductive memory cells may be locked out. The additional Erased state memory cells are identified from the prior lower page A read. No additional memory cells could have been identified in the current middle page read without a prior read level or a without a prior dummy read in the current middle page read. In B read, the sense operation is sensing two memory states of conducting Erased and A state memory cells if memory state information is only used from the current middle page read. In B read, the sense operation is sensing one memory state of conducting A state memory cells if Erased state memory cells identified in the prior lower page A read are locked out. Therefore, utilizing memory state information in a prior lower page A read in comparison to a current middle page read results in locking out one additional memory state out of two conducting memory states sensed in the B read.

For example, in F read in a middle page read, additional D state conductive memory cells may be locked out as well as locking out Erased, A, B, and C state conducting memory cells. The additional D state memory cells as well as Erased, A, B, and C state conducting memory cells may be identified from the lower page read E. Erased, A, B, and C state conducting memory cells could have also been identified in the prior level D read of the current middle page read. In F read, the sense operation is sensing two memory states of the conducting D and E state memory cells if only memory cells identified in the prior D level read of the current page read are locked out. In F read, the sense operation is sensing one conducting memory cell state in an E memory state if D state memory cells identified in the prior lower page E read are locked out. Therefore, utilizing memory state information in a prior lower E page read in comparison to a prior D read level in a current middle page read results in locking out one additional memory state out of two conducting memory states sensed in the F read.

For example, in C read in an upper page read, additional Erased and A state conductive memory cells may be locked out. The additional Erased and A state memory cells are identified from the middle page B read. No additional memory cells could have been identified in the current upper page read without a prior read level or without a dummy read in the current upper page read. In C read, the sense operation is sensing three memory states of the conducting Erased, A, and B state memory cells if memory state information is only used from the current upper page read. In C read, the sense operation is sensing one memory state of conducting B state memory cells if Erased and A state memory cells identified in the prior middle page B read level are locked out. Therefore, utilizing information in a prior middle page B read level in comparison to a current upper page read results in locking out two additional memory states out of the three conductive memory states sensed in the C read.

For example, in G read in a upper page read, additional C, D, and E state conductive memory cells may be locked out as well as locking out Erased, A, and B state conducting memory cells. The additional C, D, and E state memory cells as well as Erased, A, and B state conducting memory cells may be identified from the middle page F read. Erased, A, and B state conducting memory cells could have also been identified in the prior level of the current upper page C read. In G read, the sense operation is sensing four memory states of the conducting C, D, E, and F state memory cells if only memory cells identified in the current upper page read are locked out. In G read, the sense operation is sensing one conducting memory cell state in an F memory state if C, D, and E state memory cells identified in the prior middle page F read are additionally locked out. Therefore, utilizing information in a prior middle page F read in comparison to a prior C read level in a current upper page read results in locking out three additional memory states out of four conductive memory states sensed in the G read.

FIG. 8 is a schematic diagram illustrating another embodiment of 3-bit gray coding represented by the eight memory states. In this embodiment, Erased memory state represents “111”, A memory state represents “101”, B memory state represents “001”, C memory state represents “011”, D memory state represents “010”, E memory state E represents “110”, F memory state represents “100”, and G memory state represents “000.” The 3 code bits, “lower”, “middle” and “upper” bits, may be read or programmed separately. For example, in a first round, the lower bits of the memory cells may be read. In a second round, the middle bits of the memory cells may be read. In a third round, the upper bits of the memory cells may be read. Similarly in programming, in a first round the lower bits of the memory cells may be programmed and verified. In a second round the middle bits of the memory cells may be programmed and verified. In a third round the upper bits of the memory cells may be programmed and verified.

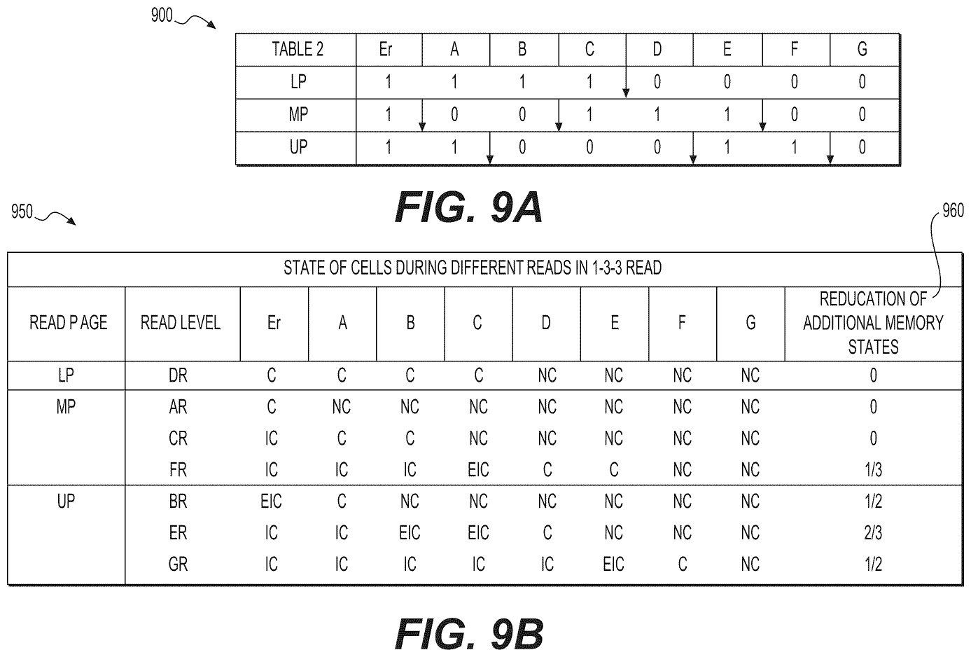

FIG. 9A is a schematic read level chart 900 illustrating one embodiment of a read operation utilizing the method 600 of FIG. 6. Read level chart 900 illustrates a read operation discerning the lower bits, middle bits, and upper bits of the 8-state memory encoded with a Gray code of FIG. 8 using a 1-3-3 read scheme. The read scheme includes three pages of reads of a lower page read, a middle page read, and an upper page read. In the lower page read, one demarcation threshold voltage is provided to identify memory cells with one read level to discern the lower bits. In the middle page read, three demarcation threshold voltages are provides to identify memory cells with three read levels to discern the middle bits. In the upper page read, three demarcation threshold voltages are provides to identify memory cells with three read levels to discern the upper bits. In the read scheme, certain memory cells in certain memory states are locked out during a read level so that power is not drained unnecessarily. Memory cells may be locked out by inhibiting the conductive cells or by having their conduction currents turned off by grounding their bit lines.

FIG. 9B is a table 750 illustrating one embodiment of locking out or inhibiting conducting cells during a read level to reduce ICC during a read operation following a read scheme of read level chart 900 of FIG. 9A. The entry “c” represents non-inhibited conductive cells during a particular read level. The entry “nc” represents non-conductive cells during a particular read level. The entry “ic” represents inhibited conductive cells during a particular read level. The entry “eic” represents extra or additional inhibited conductive cells during a particular read level in which the extra or additional inhibited conductive cells are identified from a prior read level from prior page read.

A lower page read comprising one read level with a single level D read relative to demarcation of D_{D} may discern the the lower bits of the memory cells. In the single D read, those memory cells with programmed threshold voltages less than the demarcation threshold voltage D_{D} are detected.

A middle page read comprising a three level read with a first level A read relative to demarcation threshold voltage of D_{A}, a second level C read relative to demarcation threshold voltage D_{c}, and a third level F read relative to demarcation threshold D_{F} may discern the middle bits of the memory cells. In the first level A read, those memory cells with programmed threshold voltages less than the demarcation threshold voltage D_{A} are detected. In the first level A read, no memory cells are locked out. In the second level C read, those memory cells with programmed threshold voltages less than the demarcation threshold voltage D_{C} are detected. In the second level C read, Erased state memory cells previously identified under A read in the current middle page may be locked our during C read. In the third level F read, those memory cells with programmed threshold voltages less than the demarcation threshold voltage D_{F} are detected. In the third level of read F, Erased, A, B, and C state memory cells previously identified under D read from the prior lower page read may be locked out during F read.

An upper page read comprising a three level read with a first level B read relative to demarcation of D_{B}, a second level E read relative to demarcation threshold voltage D_{E}, and a third level G read relative to demarcation of D_{G} may discern the upper bits. In the first level B read, those memory cells with programmed threshold voltages less than the demarcation threshold voltage D_{B} are detected. In the first level B read, Erased state memory cells previously identified under A read from the prior middle page read may be locked out during B read. In the second level E read, those memory cells with programmed threshold voltages less than the demarcation threshold voltage D_{E} are detected. In the second level E read, Erased, A, B, and C state memory cells previously detected under D read from prior lower page read may be locked out. In the third level G read, those memory cells with programmed threshold voltages less than the demarcation threshold voltage D_{G} are detected. In the third level G read, Erased, A, B, C, D, and E previously detected under F read from prior middle page read may be locked out.

Locking out additional memory cells identified in a prior read level from a prior page read as compared to locking out memory cells identified in a prior level from a current page reduces the number of cells sensed and reduces the Icc or power consumed. Column 960 of table 950 indicates the fraction or percentage of additional memory states locked using prior read level from a prior page read relative the remaining conductive states identified simply by using a prior read level from current page read. The additional memory states locked out are identified from a prior read level which could not have been identified from a prior level in a page read.

For example, in F read in a middle page read, additional C state conductive memory cells may be locked out as well as locking out Erased, A, and B state conducting memory cells. The additional C state memory cells as well as Erased, A, and B state conducting memory cells may be identified from the lower page D read. Erased, A, and B state conducting memory cells could have also been identified in the prior level C read of the current middle page read. In F read, the sense operation is sensing three memory states of the conducting C, D, and E state memory cells if only memory cells identified in the prior C level read of the current page read are locked out. In F read, the sense operation is sensing two conducting memory cell states in a D or E memory state if addition C state memory cells identified in the prior lower page D read are locked out. Therefore, utilizing memory state information in a prior lower page D read in comparison to a prior C read level in a current middle page read results in locking out one additional memory state out of three conducting memory states sensed in the F read.

For example, in B read in an upper page read, additional conductive memory cells in Erased memory states may be locked out. The additional Erased state memory cells are identified from the middle page A read. No additional memory cells could have been identified in the current upper page read without a prior read level or a without a prior dummy read in the current middle page read. In B read, the sense operation is sensing two memory states of conducting Erased and A state memory cells if memory state information is only used from the current upper page read. In B read, the sense operation is sensing one memory state of conducting A state memory cells if Erased state memory cells identified in the prior middle page A read are locked out. Therefore, utilizing memory state information in a prior middle page A read in comparison to a current upper read results in locking out one additional memory state out of two conducting memory states sensed in the B read.

For example, in E read in an upper page read, additional B and C state conductive memory cells may be locked out as well as locking out Erased and A state conducting memory cells. The additional B and C state memory cells as well as Erased and A state conducting memory cells may be identified from the lower page D read. Erased and A state conducting memory cells could have also been identified in the prior level of the current upper page B read. In E read, the sense operation is sensing three memory states of the conducting B, C, and E state memory cells if only memory cells identified in the current upper page B read level are locked out. In E read, the sense operation is sensing one memory state of conducting D state memory cells if additional B and C state memory cells identified in the prior lower page D read are additionally locked out. Therefore, utilizing information in a prior lower page D read in comparison to a prior B read level in a current upper page read results in locking out two additional memory states out of three conductive memory states sensed in the E read.

For example, in G read in a upper page read, additional E state conductive memory cells may be locked out as well as locking out Erased, A, B, C, and D state conducting memory cells. The additional E state memory cells as well as Erased, A, B, C, and D state conducting memory cells are identified from the middle page F read. Erased, A, B, C, and D state conducting memory cells could have also been identified in the prior level of the current upper page E read. In G read, the sense operation is sensing two memory states of the conducting E and F state memory cells if only memory cells identified in the current upper page E read level are locked out. In G read, the sense operation is sensing one conducting memory cell state in an F memory state if additional E state memory cells identified in the prior middle page F read are additionally locked out. Therefore, utilizing information in a prior middle page F read in comparison to a prior E read level in a current upper page read results in locking out one additional memory states out of two conductive memory states sensed in the G read.

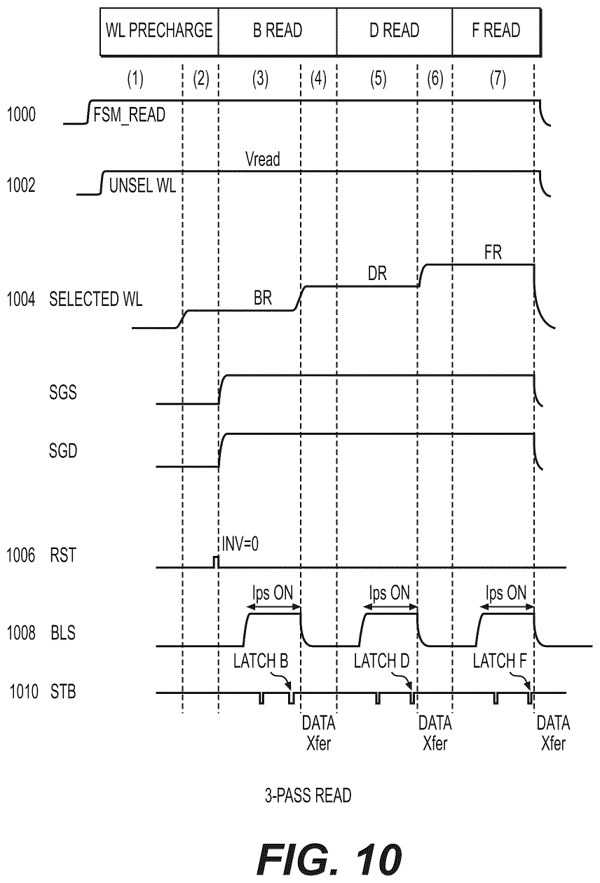

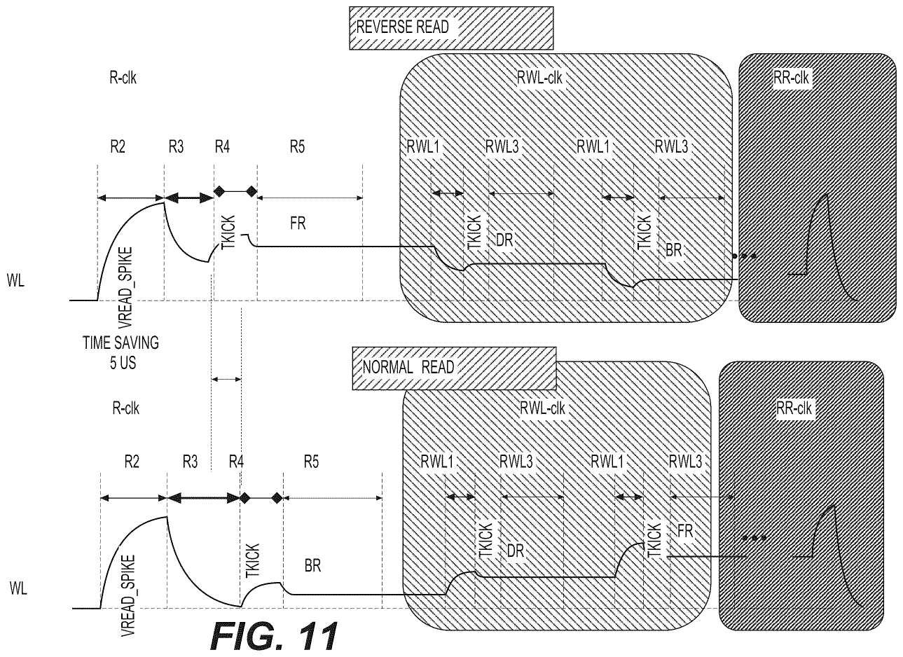

FIG. 10 is a timing diagram of the operation of the sense module 130, 480 shown in FIG. 1 and FIG. 5 during the 3-pass read as applied to a NAND memory cell that is part of a memory page in parallel, but other timing, and sense modules are possible. The timing diagram will be described in reference to middle page read of the 2-3-2 read scheme of FIGS. 7A-7B. This example shows a 3-level read of B read, D read, and F read relative to demarcation threshold voltage of D_{B}, demarcation threshold voltage D_{D}, and demarcation threshold D_{F} respectively. At the beginning of each read level, the memory cells which are not locked out will have their bit lines selected for precharged. The locked out memory cells will be discharged to ground. Selected word lines signal are supplied a voltage to the control gate of the selected cell in the NAND string to set a demarcation threshold voltage, such as a demarcation threshold voltage D_{B} in anticipation of the B read suboperation. A strobe signal STB enables a latching of the results of the read suboperation.

FIG. 10 shows the read operation to be divided into seven phases, with phases (1) and (2) grouped under a world line precharge suboperation, followed by phases (3) and (4) under B read, phases (5) and (6) under D read and phase (7) under F read suboperations respectively. Reference numeral 1000 shows that the read operation is timed at the start and end by the FSM_READ signal rising and falling respectively.

The world line precharge suboperation begins at phase (1) with the unselected word lines of the NAND chain precharging with the rise of the Unsel WL signal as shown with reference numeral 1002. This supplies a voltage of Vread (e.g. 5.5V) to the control gates of the unselected cells in the NAND chain in order to turn them fully on. At phase (2), the selected word line of the NAND chain begins precharging with the rise of the Selected WL signal as shown with reference numeral 1004. This supplies a voltage BR to the control gate of the selected cell in the NAND chain and effectively sets the demarcation threshold voltage D_{B} in anticipation of the B read suboperation to follow.

The B read suboperation begins at phase (3) with the signal RST resetting the sense amplifier's output signal INV to zero (reference numeral 1006). At the same time, the NAND chain is enabled for connection to the bit line by the signals SGS and SGD turning on a pair of select transistors of the NAND chain. The bit line is then coupled to the sense module by an enabling signal BLS (reference numeral 1008). At that moment, the precharge/clamp circuit 640 in the sense module charges up the bit line to a predetermined voltage (e.g. 0.5V) against a draining conduction current, I_{DS}, of the memory cell (shown as “I_{DS} ON” with reference numeral 1008. As soon as the bit line voltage is stable, a strobe signal STB enables a latching of the result of the cell current discriminator 650 into the latch 660 (shown as “Latch B” or “Latch D” or “Latch F” with reference numeral 1010). If the programmed threshold voltage of the memory cell is less than that of the demarcation threshold D_{B}, (or equivalently, the cell's conduction current is higher than a demarcation current) the node SEN or SEN2 will be drained down to LOW by the conduction current. This will result in a latch result with an INV signal at HIGH. Conversely, if the programmed threshold voltage of the memory cell is higher than D_{B}, SEN2 will be detected to be HIGH and INV will be latched LOW. As soon as the data from the sense amplifier is latched, the signal BLS goes LOW, thereby disconnecting the memory cell from the sense module.

For those higher current memory cells where the sensing results in the signal INV being latched at HIGH, a pull-down circuit 486 pulls down their bit lines to ground. This effectively turns off the conduction currents and the power drain of those memory cells. In a preferred implementation, an additional earlier reading (see first strobe STB in phase (3) of reference numeral 1010 is made by the sense amplifier with a limited bit line pull-up. This will identify those memory cells with even higher conduction current states and have their bit lines latched to ground as soon as possible in order to turn off their conduction currents.

In phase (4), the data in the SEN2 is transferred out via the readout bus 499 when the transfer gate 488 is enabled by the signal NCO. This is denoted by “Data Xfer” in FIG. 10.

The suboperations D read and F read are each similar to that of B read, with corresponding shifting of the selected WL voltage to DR and FR respectively.

According to an aspect, it may be preferable to sense progressively from the lower threshold voltage (such as from state “B”). This means the higher current cells are identified first for early disposal. If the cell has a programmed threshold voltage less than D_{B}, it is regarded as a conducting cell. The conducting cell will be discharged to ground after sensing at “B”. This effectively turns off the conduction current in the cell. If the cell has a programmed threshold voltage higher than D_{B}, then it is regarded as non-conducting at “B” and the bit line will be kept at a constant value and not discharged. For the second suboperation of sensing at “D” level, only the bit lines of the non-conducting cells at “B” need be selectively charged up. This means that the sense module latches for the page are not reset to force INV back to zero (i.e., not reset to clear the bit line pulldown with INV=1). In this way, the cells which have a programmed threshold voltage less than D_{B} will not be charged up, thereby saving power. It will be seen that with each successive sensing, more and more of the memory cell in the page are turned off as they are irrelevant to subsequent sensing. In this way, the power drained by the memory cells in the page is minimized.

While the example described refers to a read operation involving three demarcation threshold voltages, the methods and principle described are generally applicable to read operations with more than one pass where subsequent passes can take advantage of information obtained in an earlier pass to selectively turn off the cells irrelevant to the current pass. It should also be noted that in conventional implementations, the sensing relative to each memory state is independent of each other. That is, each sensing will go through exactly same number of steps, i.e., from phase (1) to phase (4) for each of B read, D read and F read. In the present sensing, only the first read pass, B read will reset all the sense amplifier's latches of the page to INV=0 in order to precharge all the bit lines in the page. Subsequent sensing will only charge up those bit lines with INV=0 while not charging those bit lines that have their INV's flipped during previous sensing.

In certain embodiments, the term identifying memory cells in a read level may include those memory cells that are locked out since those memory cells should have been identified in the read level. In certain embodiments, it is understood that locking out memory cells in a read level may utilize information or latches from one or more prior read levels from a prior page read alone or in combination with a current page read.

As discussed, memory cells may have threshold voltage windows partitioned into several regions representing several memory states. The regions are demarcated by the set of demarcation threshold voltages. Comparing the programmed threshold voltage with a plurality of demarcation threshold voltages when sensing a memory cell determines in which region the programmed threshold voltage lies. At a subsequent page read, the memory cells with programmed threshold voltages lower than the current demarcation threshold voltage can be identified from a prior page read and can be locked out. Thus, turning-off or inhibiting the conduction current of the previously identified memory cells from prior page reads (alone or in combination with previously identified memory cells form a prior read level from a current page read) reduces the current and power consumed.

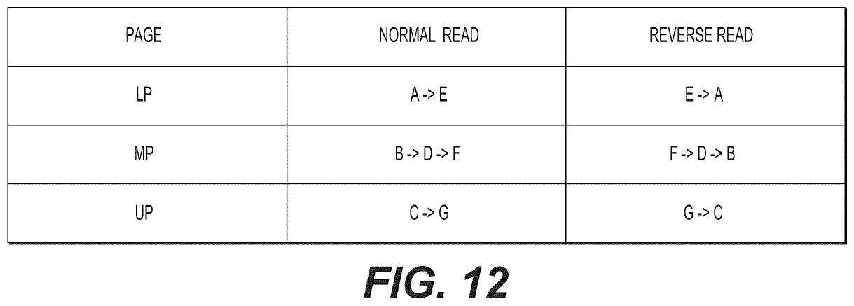

FIG. 11 shows an example series of read voltages applied to a selected word line for both a normal read and a reverse read when reading a middle page. Various time periods or portions of the period of time in which the read operation occurs are shown. These time periods include a first verify stage R-clk, a second program-verify stage RWL-clk, and a discharge stage RR-clk. The first verify stage R-clk is further divided into periods including a second portion R2, third portion R3, fourth portion R4, and settling period R5 of the first verify stage R-clk. Similarly, the second program-verify stage RWL-clk can include periods RWL1 and RWL3. In addition, a “kicking voltage” (i.e., an overshoot or undershoot of the voltage) may be applied to the selected word line in the time period labeled Tkick (e.g., during R4 and between RWL1 and RWL3) to help the voltage on the selected word line reach the target or reference voltage more quickly. As shown, for the normal read (upper portion of FIG. 11), the series of read voltages become increasing higher in magnitude with each successive data state that is being sensed. In contrast, for the reverse order read or reverse read (lower portion of FIG. 11), the read voltages of the series become increasing lower in magnitude with each successive data state that is being sensed. FIG. 12 is a table illustrating the sequences of the data states being sensed for each of a lower page, middle page, and upper page for both the normal read and the reverse read. As previously discussed, the reverse read can improve the speed of the read operation by reducing the transition from the initial voltage spike (VREAD_SPIKE) to the first one of the series of read voltages. For example, with the middle page read, the word line voltage ramps from VREAD_SPIKE (~10V) to the F state (~5V), in contrast with normal read sequence the word line voltage ramps down from VREAD_SPIKE (~10V) to B state (~1V).

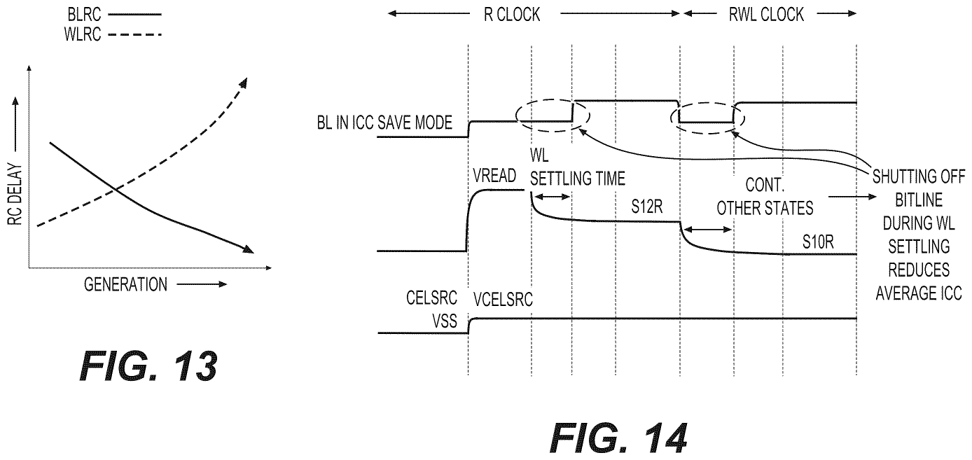

As discussed, the timing of voltages applied to selected ones of the word lines relative to those applied to bit lines coupled to the memory cells being read can affect both current consumption of the memory apparatus as well as read timing margin. FIG. 13 shows a plot of resistive-capacitive (RC) delay versus generations of memory apparatuses. In every new generation of memory apparatuses, the bit line length may be reduced by 30% because approximately 30% of the lateral scaling (Y-direction) of the die to maintain 30% bit growth. This results in decrease in bit line resistive-capacitive (BLRC) delay. However, because of the decrease in the oxide-nitride (ON) pitch from generation to generation, word line resistive-capacitive (WLRC) delay increases and word line settling time will limit the read time Tread in future generations of memory apparatuses. FIG. 14 is a plot of the bit line voltage applied to the bit lines (BL), word line voltage applied to a selected one of the word lines, and the cell source voltage to the source line during a portion of a read operation. As shown, during the word line voltage transition (i.e., word line (WL) settling time, indicated by the two horizontal double ended arrows shown on the waveform for word line voltage applied to the selected one of the word lines), current consumption (ICC) can be saved by temporarily cutting off the bit line (as shown in FIG. 14) during the word line settling time. On some memory apparatuses, this is confirmed to provide approximately 8% average ICC saving.

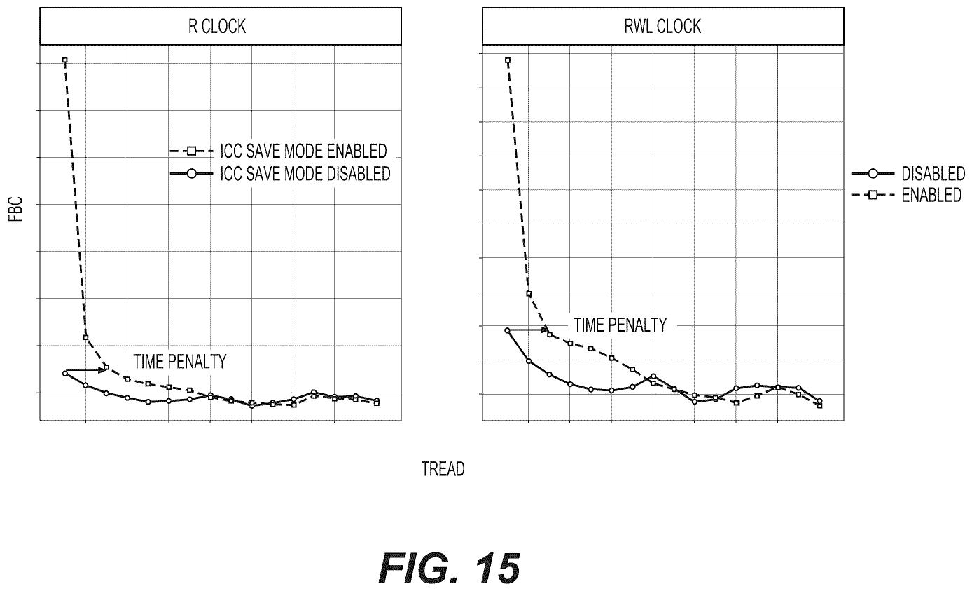

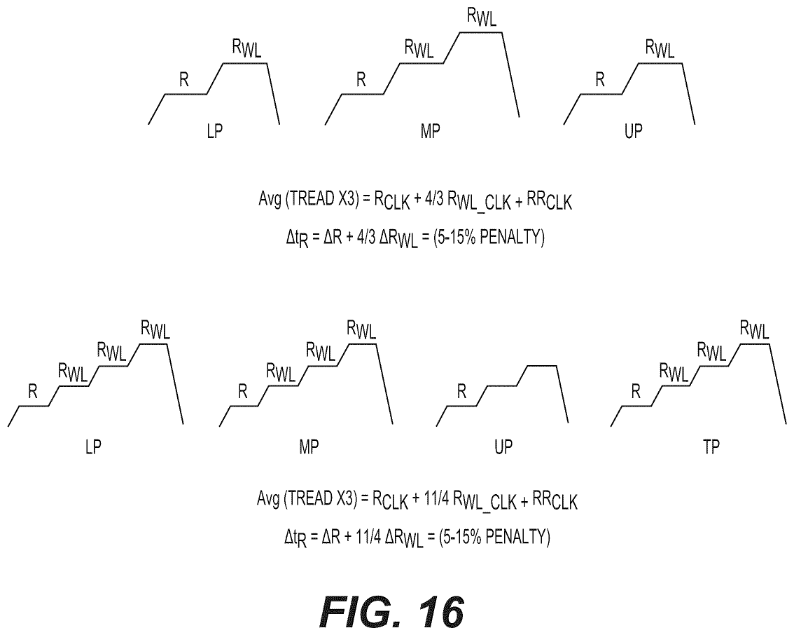

FIG. 15 is a plot of failure bit count (FBC) versus the read time (Tread) for two periods of time (R clock and RWL clock) during a read operation with the current consumption savings with (ICC save mode enabled) and without temporarily cutting off the bit line shown in FIG. 14 (ICC save mode disabled). FIG. 16 shows diagrams showing the quantity of the two periods of time (R clock and RWL clock) utilized in read operations involving lower pages (LP), middle pages (MP), and upper pages (UP) when the memory cells read are triple level (i.e., 3 bits per memory cell) (TLC) and involving lower pages (LP), middle pages (MP), upper pages (UP), and top pages (TP) when the memory cells read are four level (i.e., 4 bits per memory cell) (QLC) along with average read time Tread and change in read time ΔtR due to the current consumption savings with temporarily cutting off the bit line shown in FIG. 14. As shown, when using the delayed bit line ramp to save ICC, read timing margin can will be reduced by approximately 5-15%. Insufficient time for the bit line to settle before the read can be the reason for the reduced timing margin.

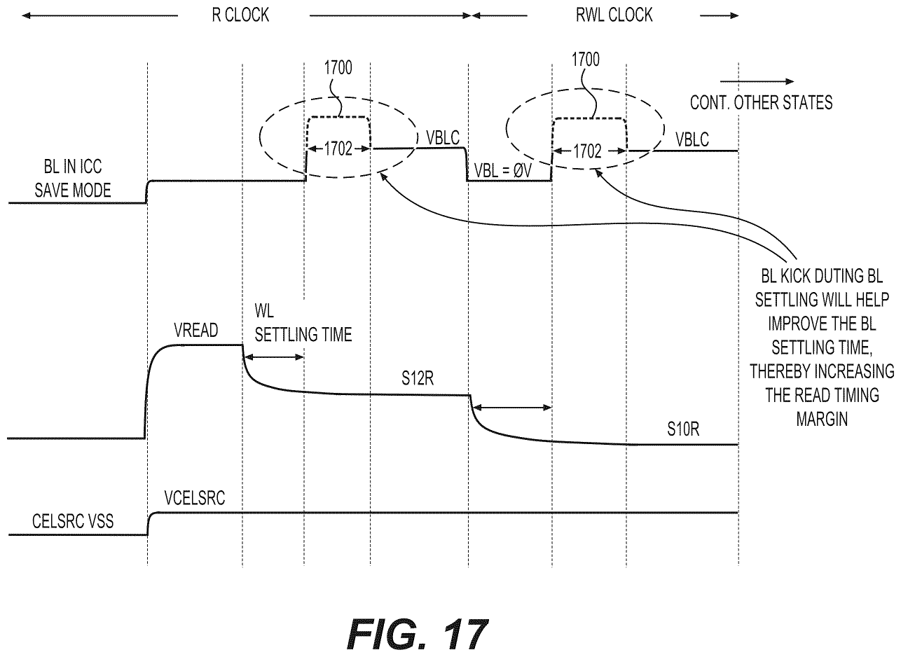

Consequently, described herein is a memory apparatus (e.g., memory device 100 in FIG. 1) including memory cells (e.g., memory cell 10 in FIG. 2) connected to one of a plurality of word lines (e.g., word lines WL₀-WL₃₁ in FIG. 5). The memory cells are disposed in memory holes (e.g., NAND chain 50 in FIG. 5) each connected to one of a plurality of bit lines (e.g., bit line 36 of FIG. 5). The memory cells are configured to retain a threshold voltage Vt or Vth corresponding to one of a plurality of memory states (e.g., “Er”, “A”, “B”, “C”, “D”, “E”, “F” and “G” in FIGS. 4 and 8). The apparatus also includes a control circuit (e.g., control circuitry 110, controller 122, row decoder 124, source control circuits 127, read write circuits 128, sense modules 130, and column decoder 132 in FIG. 1). FIG. 17 is a plot of the bit line voltage applied to the bit lines (BL), word line voltage applied to a selected one of the word lines, and the cell source voltage to the source line during a portion of a read operation in which the read timing margin is increased by decreasing the bit line settling time without significantly changing the ICC savings realized by the scheme shown in FIG. 14. Accordingly, the control circuit is configured to perform a plurality of reads on a selected one of the plurality of word lines for each of a plurality of groupings of ones of the plurality of data states in a read operation. As shown in FIG. 17, the control means is also configured to ramp a bit line voltage applied to ones of the plurality of bit lines connected the memory holes of the memory cells being read in the read operation to a bit line kick voltage 1700 for a predetermined kick time 1702 following a word line settling time (indicated by the two horizontal double ended arrows shown on the waveform for word line voltage applied to the selected one of the word lines) in which the selected ones of the plurality of word lines ramp down to one of a plurality of read voltages each associated with one of the plurality of data states. As a result, a bit line settling time is decreased by adding the bit line kick voltage 1700 for the predetermined kick time 1702 during the bit line ramp up. The bit line ramp up may be a delayed ramp up, such as that utilized in FIG. 14 to further save ICC. Such a kick can eliminate the bit line settling time bottleneck in the ICC save mode shown in FIG. 14 and helps to increase the read performance.

According to one aspect of the disclosure and still referring to FIG. 17, the control means is further configured to ramp the bit line voltage applied to ones of the plurality of bit lines connected the memory holes of the memory cells being read in the read operation back down to a clamping voltage VBLC after the predetermined kick time 1702. In other words, the predetermined kick time 1702 may not continue until the bit line voltage ramps down to 0 volts (or another low voltage).

As discussed above, the plurality of word lines and a plurality of dielectric layers may extend horizontally and overlay one another in an alternating fashion in a stack. The memory holes (e.g., NAND chain 50 in FIG. 5) extend vertically through the stack. The memory cells are connected in series between a drain-side select gate transistor (e.g., drain side select lines SGD of FIG. 5) on a drain-side of each of the memory holes and a source-side select gate transistor (e.g., source side select lines SGS of FIG. 5) on a source-side of each of the memory holes. The drain-side select gate transistor of each of the memory holes is connected to one of the plurality of bit lines (e.g., bit line 36 of FIG. 5) and the source-side select gate transistor of each of the memory holes is connected to a source line. (e.g., immediately below the source side select lines SGS of FIG. 5). The control means is further configured to apply a cell source voltage VCELSRC to the source line throughout the read operation and to the ones of the plurality of bit lines connected the memory holes of the memory cells being read during the word line settling time, and the bit line kick voltage 1700 has a magnitude greater than the clamping voltage VBLC plus the cell source voltage VCELSRC by a predetermined delta kick voltage. According to a further aspect, the predetermined delta kick voltage is approximately between 0.01 volts and 0.25 volts. However, it should be understood that other values of the predetermined delta kick voltage are contemplated.

According to additional aspects of the disclosure, the control means is further configured to ramp the bit line voltage applied to ones of the plurality of bit lines connected the memory holes of the memory cells being read in the read operation to the bit line kick voltage 1700 for the predetermined kick time 1702 following the word line settling time when reading the memory cells targeted for each of the plurality of data states. In other words, one bit line kick voltage 1700 is applied for the predetermined kick time 1702 during the read for each data state. Such operation is shown in FIG. 17, one kick is applied before sensing the memory cells targeted for the S12 data state (the memory cells are four level cells (QLC) (4 bits per memory cell) in the example shown) and then another kick is applied before sensing the memory cells targeted for the S10 data state.

According to another aspect, data stored in the memory cells is stored as a plurality of lower bits of a lower page and a plurality of middle bits of a middle page and a plurality of upper bits of an upper page and a plurality of top bits of a top page encoded with a code scheme. Although threshold voltage distributions for four level cells (QLC) are not shown, a code scheme used for QLC is similar to that shown in FIGS. 4 and 8 for triple level cells (TLC) in which data stored in the memory cells is stored as a plurality of lower bits (e.g., lower bit of FIGS. 4 and 8) of a lower page and a plurality of middle bits (e.g., middle bit of FIGS. 4 and 8) of a middle page and a plurality of upper bits (e.g., upper bit of FIGS. 4 and 8). For the QLC example, the plurality of data states includes, in order of the threshold voltage increasing in magnitude, an erased state and a plurality of programmed data states. Therefore, the plurality of groupings of ones of the plurality of data states includes the lower page and the middle page and the upper page and the top page.

In more detail and according to other aspects, the control means is further configured to receive a read request for one of the lower page and the middle page and the upper page and the top page. The control means is additionally configured to ramp up all of the plurality of word lines to a read pass voltage VREAD. The control means ramps down the selected ones of the plurality of word lines to the one of the plurality of read voltages (e.g., S12R) associated with an initial one of the plurality of data states associated with the one of the lower page and the middle page and the upper page and the top page during the word line settling time. In addition, the control means is configured to ramp up the bit line voltage applied to ones of the plurality of bit lines connected the memory holes of the memory cells being read in the read operation to a clamping voltage VBLC. The control means then ramps up the bit line voltage applied to ones of the plurality of bit lines connected the memory holes of the memory cells being read in the read operation to the bit line kick voltage 1700 for the predetermined kick time 1702. The control means is further configured to wait a predetermined wait time to allow the plurality of word lines and the plurality of bit lines to become stable. The control means is also configured to sense the threshold voltage of the memory cells targeted for the initial one of the plurality of data states (e.g., state S12) associated with the one of the lower page and the middle page and the upper page and the top page.

For each of a plurality of subsequent one of the plurality of data states associated with the one of the lower page and the middle page and the upper page and the top page, the control means is additionally configured to ramp down the selected ones of the plurality of word lines to the one of the plurality of read voltages (e.g., S10R) associated with one of the plurality of subsequent ones of the plurality of data states associated with the one of the lower page and the middle page and the upper page and the top page. The control means ramps down the bit line voltage to a voltage lower than the clamping voltage VBLC. The control means is then configured to ramp up the bit line voltage applied to ones of the plurality of bit lines connected the memory holes of the memory cells being read in the read operation to the clamping voltage VBLC. In addition, the control means is configured to ramp up the bit line voltage applied to ones of the plurality of bit lines connected the memory holes of the memory cells being read in the read operation to the bit line kick voltage 1700 for the predetermined kick time 1702. The control means waits the word line settling time to allow the plurality of word lines to become stable. The control means is also configured to sense the threshold voltage of the memory cells targeted for the one of the subsequent ones of the plurality of data states (e.g., state S10) associated with the one of the lower page and the middle page and the upper page and the top page.

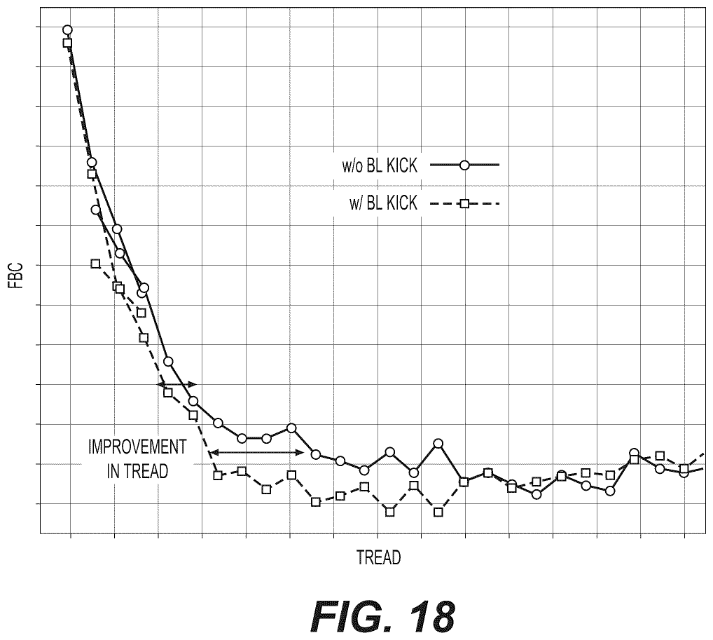

FIG. 18 is a plot of failure bit count (FBC) versus the read time (Tread) for two periods of time (R clock and RWL clock) during a read operation with the current consumption savings using the ICC save mode by temporarily cutting off the bit line, as shown in FIG. 14 during the word line settling time with and without the bit line kick voltage 1700 of FIG. 17. As shown, there is at least a 0.5 us benefit in read performance utilizing the bit line kick described above (without the bit line kick approximately 30% of the VBLC level). Further, the magnitude of the bit line kick can be optimized to realize more read time margin gain. In the ICC save mode, this improvement is expected to remain same.

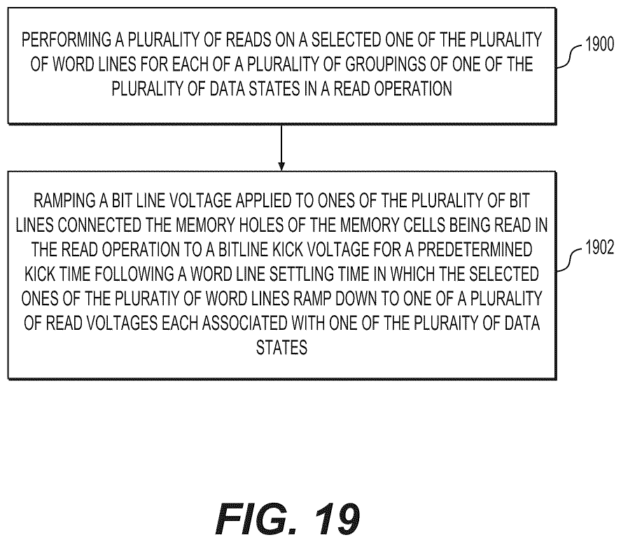

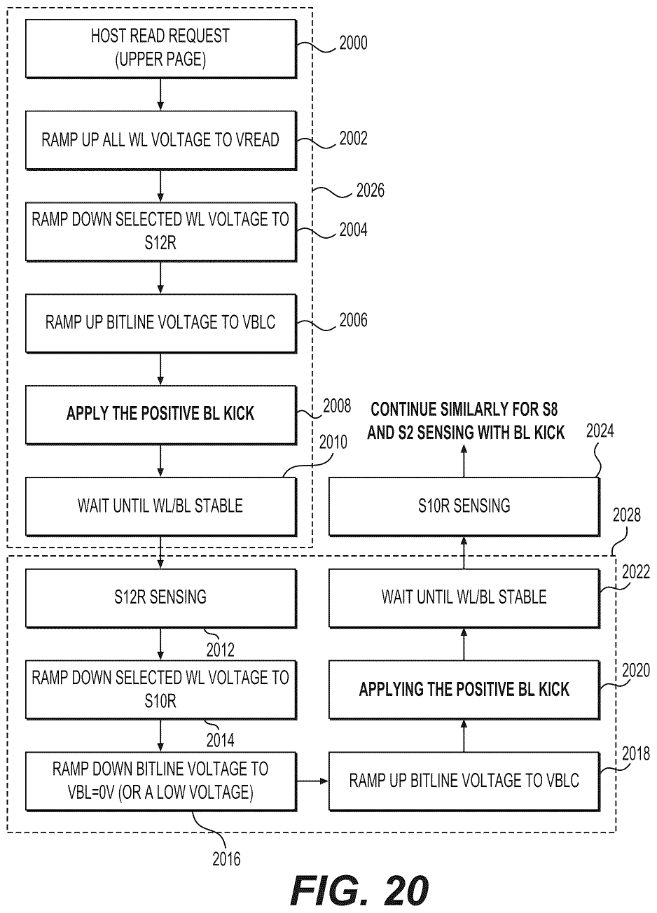

FIGS. 19 and 20 illustrate steps of a method of operating a memory apparatus is also provided. As discussed above, the memory apparatus (e.g., memory device 100 in FIG. 1) includes memory cells (e.g., memory cell 10 in FIG. 2) connected to one of a plurality of word lines (e.g., word lines WL₀-WL₃₁ in FIG. 5). The memory cells are disposed in memory holes (e.g., NAND chain 50 in FIG. 5) each connected to one of a plurality of bit lines (e.g., bit line 36 of FIG. 5). The memory cells are configured to retain a threshold voltage Vt or Vth corresponding to one of a plurality of memory states (e.g., “Er”, “A”, “B”, “C”, “D”, “E”, “F” and “G” in FIGS. 4 and 8). Referring initially to FIG. 19, the method includes the step of 1900 performing a plurality of reads on a selected one of the plurality of word lines for each of a plurality of groupings of ones of the plurality of data states in a read operation. The method also includes the step of 1902 ramping a bit line voltage applied to ones of the plurality of bit lines connected the memory holes of the memory cells being read in the read operation to a bit line kick voltage 1700 for a predetermined kick time 1702 following a word line settling time in which the selected ones of the plurality of word lines ramp down to one of a plurality of read voltages each associated with one of the plurality of data states.

According to another aspect, the method further includes the step of ramping the bit line voltage applied to ones of the plurality of bit lines connected the memory holes of the memory cells being read in the read operation back down to a clamping voltage VBLC after the predetermined kick time 1702. In other words, the predetermined kick time 1702 may not continue until the bit line voltage ramps down to 0 volts (or another low voltage).

Again, the plurality of word lines and a plurality of dielectric layers may extend horizontally and overlay one another in an alternating fashion in a stack. The memory holes (e.g., NAND chain 50 in FIG. 5) extend vertically through the stack. The memory cells are connected in series between a drain-side select gate transistor (e.g., drain side select lines SGD of FIG. 5) on a drain-side of each of the memory holes and a source-side select gate transistor (e.g., source side select lines SGS of FIG. 5) on a source-side of each of the memory holes. The drain-side select gate transistor of each of the memory holes is connected to one of the plurality of bit lines (e.g., bit line 36 of FIG. 5) and the source-side select gate transistor of each of the memory holes is connected to a source line. (e.g., immediately below the source side select lines SGS of FIG. 5). Thus, according to an aspect, the method includes the step of applying a cell source voltage VCELSRC to the source line throughout the read operation and to the ones of the plurality of bit lines connected the memory holes of the memory cells being read during the word line settling time. The bit line kick voltage 1700 has a magnitude greater than the clamping voltage VBLC plus the cell source voltage VCELSRC by a predetermined delta kick voltage. Again, according to an additional aspect, the predetermined delta kick voltage is approximately between 0.01 volts and 0.25 volts.

According to further aspects of the disclosure, the method includes the step of ramping the bit line voltage applied to ones of the plurality of bit lines connected the memory holes of the memory cells being read in the read operation to the bit line kick voltage 1700 for the predetermined kick time 1702 following the word line settling time when reading the memory cells targeted for each of the plurality of data states.

Once again, data stored in the memory cells may be stored as a plurality of lower bits of a lower page and a plurality of middle bits of a middle page and a plurality of upper bits of an upper page and a plurality of top bits of a top page encoded with a code scheme. For the QLC example, the plurality of data states includes, in order of the threshold voltage increasing in magnitude, an erased state and a plurality of programmed data states. Thus, the plurality of groupings of ones of the plurality of data states includes the lower page and the middle page and the upper page and the top page.

Referring specifically to FIG. 20 and according to further aspects of the disclosure, the method further includes the step of 2000 receiving a read request for one of the lower page and the middle page and the upper page and the top page. Next, 2002 ramping up all of the plurality of word lines to a read pass voltage VREAD. The method continues by 2004 ramping down the selected ones of the plurality of word lines to the one of the plurality of read voltages associated with an initial one of the plurality of data states associated with the one of the lower page and the middle page and the upper page and the top page during the word line settling time. The method additionally includes the step of 2006 ramping up the bit line voltage applied to ones of the plurality of bit lines connected the memory holes of the memory cells being read in the read operation to a clamping voltage VBLC. The method proceeds with the step of 2008 ramping up the bit line voltage applied to ones of the plurality of bit lines connected the memory holes of the memory cells being read in the read operation to the bit line kick voltage 1700 for the predetermined kick time 1702. In addition, the method includes the step of 2010 waiting a predetermined wait time to allow the plurality of word lines and the plurality of bit lines to become stable. The method also includes the step of 2012 sensing the threshold voltage of the memory cells targeted for the initial one of the plurality of data states associated with the one of the lower page and the middle page and the upper page and the top page.

For each of a plurality of subsequent one of the plurality of data states associated with the one of the lower page and the middle page and the upper page and the top page, the method also includes the step of 2014 ramping down the selected ones of the plurality of word lines to the one of the plurality of read voltages associated with one of the plurality of subsequent ones of the plurality of data states associated with the one of the lower page and the middle page and the upper page and the top page. The method proceeds with the step of 2016 ramping down the bit line voltage to a voltage lower than the clamping voltage VBLC. Next, 2018 ramping up the bit line voltage applied to ones of the plurality of bit lines connected the memory holes of the memory cells being read in the read operation to the clamping voltage VBLC. In addition, the method includes the step of 2020 ramping up the bit line voltage applied to ones of the plurality of bit lines connected the memory holes of the memory cells being read in the read operation to the bit line kick voltage 1700 for the predetermined kick time 1702. The method continues by 2022 waiting the word line settling time to allow the plurality of word lines to become stable. The method also includes the step of 2024 sensing the threshold voltage of the memory cells targeted for the one of the subsequent ones of the plurality of data states associated with the one of the lower page and the middle page and the upper page and the top page.

According to an aspect, the steps illustrated in box 2026 are part of an R clock period of time of the read operation and the steps illustrated in box 2028 are part of an RWL clock period of time of the read operation.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptions used herein interpreted accordingly.

What is claimed is:

1. A memory apparatus, comprising:
memory cells each connected to one of a plurality of word lines and disposed in memory holes each connected to one of a plurality of bit lines, the memory cells configured to retain a threshold voltage corresponding to one of a plurality of data states; and
a control means configured to:
perform a plurality of reads on a selected one of the plurality of word lines for each of a plurality of groupings of ones of the plurality of data states in a read operation, and
ramp a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

2. The memory apparatus as set forth in claim 1, wherein the control means is further configured to ramp the bit line voltage applied to ones of the plurality of bit lines connected the memory holes of the memory cells being read in the read operation back down to a clamping voltage after the predetermined kick time.

3. The memory apparatus as set forth in claim 2, wherein the plurality of word lines and a plurality of dielectric layers extend horizontally and overlay one another in an alternating fashion in a stack, the memory holes extend vertically through the stack, the memory cells are connected in series between a drain-side select gate transistor on a drain-side of each of the memory holes and a source-side select gate transistor on a source-side of each of the memory holes, the drain-side select gate transistor of each of the memory holes is connected to one of the plurality of bit lines and the source-side select gate transistor of each of the memory holes is connected to a source line, the control means is further configured to apply a cell source voltage to the source line throughout the read operation and to the ones of the plurality of bit lines connected the memory holes of the memory cells being read during the word line settling time, and the bit line kick voltage has a magnitude greater than the clamping voltage plus the cell source voltage by a predetermined delta kick voltage.

4. The memory apparatus as set forth in claim 3, wherein the predetermined delta kick voltage is approximately between 0.01 volts and 0.25 volts.

5. The memory apparatus as set forth in claim 1, wherein the control means is further configured to ramp the bit line voltage applied to ones of the plurality of bit lines connected the memory holes of the memory cells being read in the read operation to the bit line kick voltage for the predetermined kick time following the word line settling time when reading the memory cells targeted for each of the plurality of data states.

6. The memory apparatus as set forth in claim 1, wherein data stored in the memory cells is stored as a plurality of lower bits of a lower page and a plurality of middle bits of a middle page and a plurality of upper bits of an upper page and a plurality of top bits of a top page encoded with a code scheme, the plurality of data states includes, in order of the threshold voltage increasing in magnitude, an erased state and a plurality of programmed data states, the plurality of groupings of ones of the plurality of data states includes the lower page and the middle page and the upper page and the top page.

7. The memory apparatus as set forth in claim 6, wherein the control means is further configured to:
receive a read request for one of the lower page and the middle page and the upper page and the top page;
ramp up all of the plurality of word lines to a read pass voltage;
ramp down the selected ones of the plurality of word lines to the one of the plurality of read voltages associated with an initial one of the plurality of data states associated with the one of the lower page and the middle page and the upper page and the top page during the word line settling time;
ramp up the bit line voltage applied to ones of the plurality of bit lines connected the memory holes of the memory cells being read in the read operation to a clamping voltage;
ramp up the bit line voltage applied to ones of the plurality of bit lines connected the memory holes of the memory cells being read in the read operation to the bit line kick voltage for the predetermined kick time;
wait a predetermined wait time to allow the plurality of word lines and the plurality of bit lines to become stable;
sense the threshold voltage of the memory cells targeted for the initial one of the plurality of data states associated with the one of the lower page and the middle page and the upper page and the top page; and
for each of a plurality of subsequent one of the plurality of data states associated with the one of the lower page and the middle page and the upper page and the top page:
ramp down the selected ones of the plurality of word lines to the one of the plurality of read voltages associated with one of the plurality of subsequent ones of the plurality of data states associated with the one of the lower page and the middle page and the upper page and the top page,
ramp down the bit line voltage to a voltage lower than the clamping voltage,
ramp up the bit line voltage applied to ones of the plurality of bit lines connected the memory holes of the memory cells being read in the read operation to the clamping voltage,
ramp up the bit line voltage applied to ones of the plurality of bit lines connected the memory holes of the memory cells being read in the read operation to the bit line kick voltage for the predetermined kick time,
wait the word line settling time to allow the plurality of word lines to become stable, and
sense the threshold voltage of the memory cells targeted for the one of the subsequent ones of the plurality of data states associated with the one of the lower page and the middle page and the upper page and the top page.

8. A controller in communication with a memory apparatus including memory cells each connected to one of a plurality of word lines and disposed in memory holes each connected to one of a plurality of bit lines, the memory cells configured to retain a threshold voltage corresponding to one of a plurality of data states, the controller configured to:
instruct the memory apparatus to perform a plurality of reads on a selected one of the plurality of word lines for each of a plurality of groupings of ones of the plurality of data states in a read operation; and
instruct the memory apparatus to ramp a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

9. The controller as set forth in claim 8, wherein the controller is further configured to instruct the memory apparatus to ramp the bit line voltage applied to ones of the plurality of bit lines connected the memory holes of the memory cells being read in the read operation back down to a clamping voltage after the predetermined kick time.

10. The controller as set forth in claim 9, wherein the plurality of word lines and a plurality of dielectric layers extend horizontally and overlay one another in an alternating fashion in a stack, the memory holes extend vertically through the stack, the memory cells are connected in series between a drain-side select gate transistor on a drain-side of each of the memory holes and a source-side select gate transistor on a source-side of each of the memory holes, the drain-side select gate transistor of each of the memory holes is connected to one of the plurality of bit lines and the source-side select gate transistor of each of the memory holes is connected to a source line, the controller is further configured to apply a cell source voltage to the source line throughout the read operation and to the ones of the plurality of bit lines connected the memory holes of the memory cells being read during the word line settling time, and the bit line kick voltage has a magnitude greater than the clamping voltage plus the cell source voltage by a predetermined delta kick voltage.

11. The controller as set forth in claim 10, wherein the predetermined delta kick voltage is approximately between 0.01 volts and 0.25 volts.

12. The controller as set forth in claim 8, wherein the controller is further configured to instruct the memory apparatus to ramp the bit line voltage applied to ones of the plurality of bit lines connected the memory holes of the memory cells being read in the read operation to the bit line kick voltage for the predetermined kick time following the word line settling time when reading the memory cells targeted for each of the plurality of data states.

13. The controller as set forth in claim 8, wherein data stored in the memory cells is stored as a plurality of lower bits of a lower page and a plurality of middle bits of a middle page and a plurality of upper bits of an upper page and a plurality of top bits of a top page encoded with a code scheme, the plurality of data states includes, in order of the threshold voltage increasing in magnitude, an erased state and a plurality of programmed data states, the plurality of groupings of ones of the plurality of data states includes the lower page and the middle page and the upper page and the top page.

14. A method of operating a memory apparatus including memory cells each connected to one of a plurality of word lines and disposed in memory holes each connected to one of a plurality of bit lines, the memory cells configured to retain a threshold voltage corresponding to one of a plurality of data states, the method comprising the steps of:
performing a plurality of reads on a selected one of the plurality of word lines for each of a plurality of groupings of ones of the plurality of data states in a read operation; and
ramping a bit line voltage applied to ones of the plurality of bit lines connected the memory holes of the memory cells being read in the read operation to a bit line kick voltage for a predetermined kick time following a word line settling time in which the selected ones of the plurality of word lines ramp down to one of a plurality of read voltages each associated with one of the plurality of data states.

15. The method as set forth in claim 14, further including the step of ramping the bit line voltage applied to ones of the plurality of bit lines connected the memory holes of the memory cells being read in the read operation back down to a clamping voltage after the predetermined kick time.

16. The method as set forth in claim 15, wherein the plurality of word lines and a plurality of dielectric layers extend horizontally and overlay one another in an alternating fashion in a stack, the memory holes extend vertically through the stack, the memory cells are connected in series between a drain-side select gate transistor on a drain-side of each of the memory holes and a source-side select gate transistor on a source-side of each of the memory holes, the drain-side select gate transistor of each of the memory holes is connected to one of the plurality of bit lines and the source-side select gate transistor of each of the memory holes is connected to a source line, method further includes the step of applying a cell source voltage to the source line throughout the read operation and to the ones of the plurality of bit lines connected the memory holes of the memory cells being read during the word line settling time, and wherein the bit line kick voltage has a magnitude greater than the clamping voltage plus the cell source voltage by a predetermined delta kick voltage.

17. The method as set forth in claim 16, wherein the predetermined delta kick voltage is approximately between 0.01 volts and 0.25 volts.

18. The method as set forth in claim 14 further including the step of ramping the bit line voltage applied to ones of the plurality of bit lines connected the memory holes of the memory cells being read in the read operation to the bit line kick voltage for the predetermined kick time following the word line settling time when reading the memory cells targeted for each of the plurality of data states.

19. The method as set forth in claim 14, wherein data stored in the memory cells is stored as a plurality of lower bits of a lower page and a plurality of middle bits of a middle page and a plurality of upper bits of an upper page and a plurality of top bits of a top page encoded with a code scheme, the plurality of data states includes, in order of the threshold voltage increasing in magnitude, an erased state and a plurality of programmed data states, the plurality of groupings of ones of the plurality of data states includes the lower page and the middle page and the upper page and the top page.

20. The method as set forth in claim 19, further including the steps of:
receiving a read request for one of the lower page and the middle page and the upper page and the top page;
ramping up all of the plurality of word lines to a read pass voltage;
ramping down the selected ones of the plurality of word lines to the one of the plurality of read voltages associated with an initial one of the plurality of data states associated with the one of the lower page and the middle page and the upper page and the top page during the word line settling time;
ramping up the bit line voltage applied to ones of the plurality of bit lines connected the memory holes of the memory cells being read in the read operation to a clamping voltage;
ramping up the bit line voltage applied to ones of the plurality of bit lines connected the memory holes of the memory cells being read in the read operation to the bit line kick voltage for the predetermined kick time;
waiting a predetermined wait time to allow the plurality of word lines and the plurality of bit lines to become stable;
sensing the threshold voltage of the memory cells targeted for the initial one of the plurality of data states associated with the one of the lower page and the middle page and the upper page and the top page; and
for each of a plurality of subsequent one of the plurality of data states associated with the one of the lower page and the middle page and the upper page and the top page:
ramping down the selected ones of the plurality of word lines to the one of the plurality of read voltages associated with one of the plurality of subsequent ones of the plurality of data states associated with the one of the lower page and the middle page and the upper page and the top page,
ramping down the bit line voltage to a voltage lower than the clamping voltage,
ramping up the bit line voltage applied to ones of the plurality of bit lines connected the memory holes of the memory cells being read in the read operation to the clamping voltage,
ramping up the bit line voltage applied to ones of the plurality of bit lines connected the memory holes of the memory cells being read in the read operation to the bit line kick voltage for the predetermined kick time,
waiting the word line settling time to allow the plurality of word lines to become stable, and
sensing the threshold voltage of the memory cells targeted for the one of the subsequent ones of the plurality of data states associated with the one of the lower page and the middle page and the upper page and the top page.
